(19) United States
(12) Patent Application Publication
(10) Pub. No.: US 2026/0130035 A1
(43) Pub. Date: May 7, 2026

(54) DISPLAY DEVICE HAVING HIGH COLOR PURITY AND COLOR CONVERSION STRUCTURE THEREOF

(71) Applicant: HARVATEK CORPORATION, Hsinchu City (TW)

(72) Inventors: ZONG-LIANG CHEN, Hsinchu City (TW); YU-CHANG HU, Hsinchu City (TW); GUAN-YU LI, Hsinchu City (TW); Hsin-I Lu, HSINCHU COUNTY (TW); SHYI-MING PAN, Miaoli County (TW); FENG-HUI CHUANG, New Taipei City (TW)

(21) Appl. No.: 19/321,302

(22) Filed: Sep. 8, 2025

(30) Foreign Application Priority Data
Nov. 7, 2024 (TW) 113142634

(51) Int. Cl. H10H 29/85; H10H 29/855

(52) U.S. Cl. CPC H10H 29/8517; H10H 29/8552

(57) ABSTRACT

A display device having a high color purity and a color conversion structure of the display device having the high color purity. The color conversion structure is configured to convert light emitted from a blue light substrate, and includes a color conversion layer, a first filter layer disposed on the color conversion layer, and a second filter layer disposed on the first filter layer. The color conversion layer includes a blue light-transmitting region, a green conversion region, and a red conversion region. The first filter layer includes another blue light-transmitting region that corresponds in position to the blue light-transmitting region. The first and second filter layers can filter blue light of different ratios, so that color purities of red light and green light are enhanced and brightness of the blue light is ensured.

### CROSS-REFERENCE TO RELATED PATENT APPLICATION

This application claims the benefit of priority to Taiwan Patent Application No. 113142634, filed on Nov. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a field of display devices, and more particularly to a display device having a high color purity and a color conversion structure thereof.

### BACKGROUND OF THE DISCLOSURE

With the development of technology, latest display techniques have achieved significant improvement in terms of display image quality, color performance, energy consumption, etc. In various display technologies, mini light-emitting diodes (mini LEDs), micro LEDs, or organic light-emitting diode (OLEDs) have been considered key technologies in next-generation display.

An LED display is a display device that uses an array of light-emitting diodes integrated on a substrate as display pixels. In a common approach, a quantum dot material is applied to a color filter for cooperation with a blue LED backlight module, and a full color display can be achieved by photoluminescence. For example, in the structure of an existing quantum dot color filter (QDCF), a red filter unit includes red quantum dots and can emit red light after being excited by blue light, a green filter unit includes green quantum dots and can emit green light after being excited by the blue light, and a blue filter unit is formed by a transparent polymer material to allow the blue light to pass through. However, blue light from a blue LED cannot be 100% converted into the red light and the green light by the quantum dots. The blue light partially passes through the red filter unit and the green filter unit, so that a color purity of the red light and that of the green light are not high. Furthermore, if a driving current of the blue LED is large, the blue light may easily be too strong in a region where the blue filter unit is located, thereby resulting in a bluish overall display effect.

### SUMMARY OF THE DISCLOSURE

In response to the above-referenced technical inadequacies, the present disclosure provides a display device having a high color purity and a color conversion structure thereof. The color conversion structure of the present disclosure is configured to convert light emitted from a blue light substrate, and can effectively reduce negative influences of background blue light on a display color.

In order to solve the above-mentioned problems, one of the technical aspects adopted by the present disclosure is to provide a display device having a high color purity. The display device includes a blue light substrate and a color conversion structure. The blue light substrate includes a first blue light-emitting element, a second blue light-emitting element, and a third blue light-emitting element that are spaced apart from each other. The color conversion structure includes a color conversion layer, a first filter layer, and a second filter layer. The color conversion layer is disposed on the blue light substrate, and includes a blue light-transmitting region that corresponds in position to the first blue light-emitting element, a green conversion region that corresponds in position to the second blue light-emitting element, and a red conversion region that corresponds in position to the third blue light-emitting element. The first filter layer is disposed on the color conversion layer, and includes another blue light-transmitting region that corresponds in position to the blue light-transmitting region. The second filter layer is disposed on the first filter layer. An optical density for each 1 micrometer thickness of the first filter layer within a wavelength range of from 380 nm to 500 nm is from 0.4 to 0.8, and an optical density for each 1 micrometer thickness of the second filter layer within the wavelength range of from 380 nm to 500 nm is from 0.8 to 1.2.

In order to solve the above-mentioned problems, another one of the technical aspects adopted by the present disclosure is to provide a color conversion structure for converting light emitted from a blue light substrate. The blue light substrate includes a first blue light-emitting element, a second blue light-emitting element, and a third blue light-emitting element that are spaced apart from each other. The color conversion structure includes a color conversion layer, a first filter layer, and a second filter layer. The color conversion layer is disposed on the blue light substrate, and includes a blue light-transmitting region that corresponds in position to the first blue light-emitting element, a green conversion region that corresponds in position to the second blue light-emitting element, and a red conversion region that corresponds in position to the third blue light-emitting element. The first filter layer is disposed on the color conversion layer, and includes another blue light-transmitting region that corresponds in position to the blue light-transmitting region. The second filter layer is disposed on the first filter layer. An optical density for each 1 micrometer thickness of the first filter layer within a wavelength range of from 380 nm to 500 nm is from 0.4 to 0.8, and an optical density for each 1 micrometer thickness of the second filter layer within the wavelength range of from 380 nm to 500 nm is from 0.8 to 1.2.

In one of the possible or preferred embodiments, the color conversion structure includes a patterned metal layer, and the patterned metal layer is disposed on the second filter layer for division of a plurality of sub-pixel units. The first filter layer includes a first blue light-blocking region disposed on at least one side of the another blue light-transmitting region, and the second filter layer includes a second blue light-blocking region. A blue sub-pixel unit of the plurality of sub-pixel units includes the first blue light-emitting element and the blue light-transmitting region, the another blue light-transmitting region, and the second blue light-blocking region that are sequentially arranged in a direction away from a light-emitting surface of the first blue light-emitting element; a green sub-pixel unit of the plurality of sub-pixel units includes the second blue light-emitting element and the green conversion region, the first blue light-blocking region, and the second blue light-blocking region that are sequentially arranged in a direction away from a light-emitting surface of the second blue light-emitting element; and a red sub-pixel unit of the plurality of sub-pixel units includes the third blue light-emitting element and the red conversion region, the first blue light-blocking region, and the second blue light-blocking region that are sequentially arranged in a direction away from a light-emitting surface of the third blue light-emitting element.

In one of the possible or preferred embodiments, the second blue light-blocking region includes a plurality of thick layer regions and a plurality of thin layer regions that are alternately arranged, a thickness ratio of the plurality of thick layer regions to the plurality of thin layer regions is from 6:1 to 10:1, and the plurality of thick layer regions are formed into the second blue light-blocking region. The patterned metal layer includes a plurality of metal spacers that respectively correspond in position to the plurality of thin layer regions, and the plurality of thick layer regions are respectively disposed in a plurality of spaces between the plurality of metal spacers.

In one of the possible or preferred embodiments, the display device having the high color purity further includes a transparent cover that covers the color conversion structure. The patterned metal layer is disposed between the second filter layer and the transparent cover, and each of the plurality of metal spacers is interlaid between the transparent cover and a corresponding one of the plurality of thin layer regions.

In one of the possible or preferred embodiments, the first filter layer and the second filter layer each contain a yellow pigment, and the yellow pigment is a yellow organic pigment, a yellow inorganic pigment, or a combination thereof.

In one of the possible or preferred embodiments, the first filter layer and the second filter layer are each formed by a photosensitive resin composition that contains the yellow pigment, a thickness of the first filter layer is within a range of from 1.6 μm to 2.5 μm, and a thickness of the plurality of thick layer regions in the second filter layer is within a range of from 0.6 μm to 1 μm. Based on a total weight of the photosensitive resin composition forming the first filter layer being 100 wt %, a content of the yellow pigment in the photosensitive resin composition forming the first filter layer is from 40 wt % to 60 wt %. Based on a total weight of the photosensitive resin composition forming the second filter layer being 100 wt %, a content of the yellow pigment in the photosensitive resin composition forming the second filter layer is from 10 wt % to 30 wt %.

Therefore, in the display device having the high color purity and the color conversion structure thereof provided by the present disclosure, the color conversion structure includes the color conversion layer, the first filter layer disposed on the color conversion layer, and the second filter layer disposed on the first filter layer. The first filter layer includes the another blue light-transmitting region that corresponds in position to the blue light-transmitting region of the color conversion layer. Furthermore, the optical density for each 1 micrometer thickness of the first filter layer within the wavelength range of from 380 nm to 500 nm is from 0.4 to 0.8, and the optical density for each 1 micrometer thickness of the second filter layer within the wavelength range of from 380 nm to 500 nm is from 0.8 to 1.2. In this way, color purities of red light and green light are enhanced, and brightness of blue light is ensured, thereby achieving stable, high-quality, and wide color gamut display effects.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view showing a structure of a display device having a high color purity according to the present disclosure; and

FIG. 2 to FIG. 6 are each a schematic view showing a manufacturing process of the display device having the high color purity according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Unless otherwise stated, the material(s) used in any described embodiment is/are commercially available material(s) or may be prepared by methods known in the art, and the method(s) or operation(s) used in any described embodiment is/are conventional method(s) or operation(s) generally known in the related art.

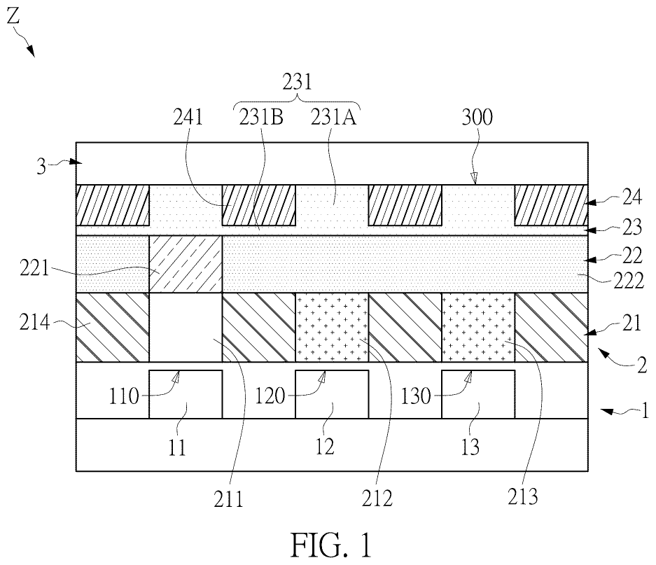

Referring to FIG. 1, an embodiment of the present disclosure provides a display device Z, which mainly includes a blue light substrate 1 and a color conversion structure 2. The color conversion structure 2 is disposed on the blue light substrate 1 for converting light emitted from the blue light substrate 1. The color conversion structure 2 includes a color conversion layer 21, a first filter layer 22 disposed on the color conversion layer 21, and a second filter layer 23 disposed on the first filter layer 22. The first filter layer 22 and the second filter layer 23 can cooperate with each other to filter background blue light, so as to effectively reduce negative influences of the background blue light on a display color. It is worth mentioning that the first filter layer 22 and the second filter layer 23 can filter blue light of different ratios, so that color purities of red and green pixels can be enhanced, and a blue pixel can be maintained to have certain brightness. In the present disclosure, an optical density (OD) for each 1 micrometer thickness of the first filter layer 22 within a wavelength range of from 380 nm to 500 nm is from 0.4 to 0.8, and an optical density for each 1 micrometer thickness of the second filter layer 23 within the wavelength range of from 380 nm to 500 nm is from 0.8 to 1.2.

The blue light substrate 1 includes a first blue light-emitting element 11, a second blue light-emitting element 12, and a third blue light-emitting element 13 that are spaced apart from each other, so as to respectively form blue, green, and red sub-pixel units. The first blue light-emitting element 11, the second blue light-emitting element 12, and the third blue light-emitting element 13 can adopt a mini light-emitting diode (mini LED), a micro LED, or an organic light-emitting diode (OLED). The color conversion layer 21 is disposed on the blue light substrate 1, and includes a blue light-transmitting region 211 that corresponds in position to the first blue light-emitting element 11, a green conversion region 212 that corresponds in position to the second blue light-emitting element 12, and a red conversion region 213 that corresponds in position to the third blue light-emitting element 13. The blue light-transmitting region 211 allows blue light emitted by the first blue light-emitting element 11 to penetrate through the color conversion layer 21, the green conversion region 212 can convert blue light emitted by the second blue light-emitting element 12 into green light, and the red conversion region 213 can convert blue light emitted by the third blue light-emitting element 13 into red light.

In practice, in the color conversion layer 21, no wavelength conversion material is present in the blue light-transmitting region 211, a wavelength conversion material (e.g., green quantum dots) is present in the green conversion region 212, and another wavelength conversion material (e.g., red quantum dots) is present in the red conversion region 213. However, the present disclosure is not limited to the examples mentioned above. In addition, the color conversion layer 21 can further include a black matrix 214, so as to separate the blue light-transmitting region 211, the green conversion region 212, and the red conversion region 213 from each other. That is, the blue light-transmitting region 211, the green conversion region 212, and the red conversion region 213 are sequentially arranged within the black matrix 214. Accordingly, color crosstalk in sub-pixel units of different colors can be effectively prevented.

In FIG. 1, only three blue light-emitting elements (i.e., the first blue light-emitting element 11, the second blue light-emitting element 12, and the third blue light-emitting element 13) are illustrated. However, in actuality, the blue light substrate 1 further includes numerous additional blue light-emitting elements, so that a specific number of pixel units can be formed.

The first filter layer 22 and the second filter layer 23 can both absorb the blue light, and allow penetration of light having a longer wavelength (e.g., the green light and the red light). An absorption rate of the first filter layer 22 with respect to the blue light is greater than that of the second filter layer 23. That is, a transmittance of the first filter layer 22 with respect to the blue light is less than that of the second filter layer 23. The first filter layer 22 and the second filter layer 23 are each formed by a photosensitive resin composition, and the photosensitive resin composition contains a yellow pigment, such as a yellow organic pigment, a yellow inorganic pigment, or a combination thereof. The yellow organic pigment can be C.I. Pigment Yellow 12, C.I. Pigment Yellow 13, C.I. Pigment Yellow 14, C.I. Pigment Yellow 17, C.I. Pigment Yellow 20, C.I. Pigment Yellow 24, C.I. Pigment Yellow 31, C.I. Pigment Yellow 55, C.I. Pigment Yellow 83, C.I. Pigment Yellow 93, C.I. Pigment Yellow 109, C.I. Pigment Yellow 110, C.I. Pigment Yellow 128, C.I. Pigment Yellow 138, C.I. Pigment Yellow 139, C.I. Pigment Yellow 150, C.I. Pigment Yellow 153, C.I. Pigment Yellow 154, C.I. Pigment Yellow 155, C.I. Pigment Yellow 166, C.I. Pigment Yellow 168, C.I. Pigment Yellow 180, C.I. Pigment Yellow 185, C.I. Pigment Yellow 211, C.I. Pigment Yellow 219, etc. The yellow inorganic pigment can be bismuth yellow (e.g., bismuth vanadate (BiVO₄)), chrome yellow, iron oxide yellow, cadmium yellow, titan yellow, etc.

In practice, the first filter layer 22 can be formed by exposure and development. Based on a total weight of the photosensitive resin composition forming the first filter layer 22 being 100 wt %, the photosensitive resin composition forming the first filter layer 22 contains 40 wt % to 60 wt % (preferably 46 wt % to 48 wt %) of the yellow pigment. In a process of forming the second filter layer 23, exposure and development are not required, and relevant technical details will be provided below. Based on a total weight of the photosensitive resin composition forming the second filter layer 23 being 100 wt %, the photosensitive resin composition forming the second filter layer 23 contains 10 wt % to 30 wt % (preferably 23 wt % to 25 wt %) of the yellow pigment.

Specifically, the absorption rate of the first filter layer 22 within the wavelength range of from 380 nm to 500 nm is from 60% to 80%, such as 78% (but is not limited thereto). The first filter layer 22 includes another blue light-transmitting region 221 that corresponds in position to the blue light-transmitting region 211 of the color conversion layer 21 and a first blue light-blocking region 222 disposed on at least one side of the blue light-transmitting region 221. As such, the blue light emitted by the first blue light-emitting element 11 can also penetrate through the first filter layer 22, and the first filter layer 22 can block a portion of the blue light that is emitted by the second blue light-emitting element 12 and is not completely converted by the green conversion region 212 and a portion of the blue light that is emitted by the third blue light-emitting element 13 and is not completely converted by the red conversion region 213. Moreover, the absorption rate of the second filter layer 23 within the wavelength range of from 380 nm to 500 nm is from 10% to 40%, such as 13% (but is not limited thereto). The second filter layer 23 merely includes a second blue light-blocking region 231, but does not include a blue light-transmitting region. As such, an excessive portion of the blue light emitted by the first blue light-emitting element 11 and an unwanted portion of the blue light that is emitted by each of the second blue light-emitting element 12 and the third blue light-emitting element 13 and that is not filtered out by the first filter layer 22 can all be eliminated by the second filter layer 23. In this way, color purities of the red light and the green light are enhanced, and brightness of the blue light is ensured, thereby achieving stable, high-quality, and wide color gamut display effects.

It should be noted that, while a thickness of the first filter layer 22 can be increased to eliminate excessive blue light of the display device Z and prevent a bluish overall display effect, the displayed brightness of the blue light will not be ideal. That is to say, compared with a thickness increment of the first filter layer 22, the display device Z can have better technical effects due to the second filter layer 23. Cooperation of the second filter layer 23 and the first filter layer 22 cannot be replaced by increasing the thickness of the first filter layer 22.

In the present embodiment, the color conversion structure 2 further includes a patterned metal layer 24, so as to prevent light from flowing along the second filter layer 23 and negatively affecting a color purity of each color pixel. The patterned metal layer 24 can not only define a predetermined setting region for each color pixel, but can also aid in positioning during a stacking process of the color conversion layer 21, the first filter layer 22, and the second filter layer 23. Specifically, the patterned metal layer 24 is disposed on the second filter layer 23, so that the second filter layer 23 is formed to have a structure matching with a patterned structure of the patterned metal layer 24 for division of the sub-pixel units (which include the blue sub-pixel unit, the green sub-pixel unit, and the red sub-pixel unit).

As shown in FIG. 1, the blue sub-pixel unit includes the first blue light-emitting element 11, and the blue light-transmitting region 211, the blue light-transmitting region 221, and a region of the second filter layer 23 that are sequentially arranged in a direction away from a light-emitting surface 110 of the first blue light-emitting element 11. The region of the second filter layer 23 corresponds in position to the blue light-transmitting region 221. The green sub-pixel unit includes the second blue light-emitting element 12, and the green conversion region 212, the first blue light-blocking region 222, and the second blue light-blocking region 231 that are sequentially arranged in a direction away from a light-emitting surface 120 of the second blue light-emitting element 12. The red sub-pixel unit includes the third blue light-emitting element 13, and the red conversion region 213, the first blue light-blocking region 222, and the second blue light-blocking region 231 that are sequentially arranged in a direction away from a light-emitting surface 130 of the third blue light-emitting element 13.

In the present embodiment, the second blue light-blocking region 231 of the second filter layer 23 includes a plurality of thick layer regions 231A and a plurality of thin layer regions 231B that are alternately arranged. A thickness ratio of the thick layer regions 231A to the thin layer regions 231B is from 6:1 to 10:1. In addition, the patterned metal layer 24 includes a plurality of metal spacers 241 that respectively correspond in position to the thin layer regions 231B. The thick layer regions 231A are disposed in spaces between the metal spacers 241, respectively. In practice, the thickness of the first filter layer 22 is within a range of from 1.6 μm to 2.5 μm, and a thickness of the thick layer regions 231A in the second filter layer 23 is within a range of from 0.6 μm to 1 μm.

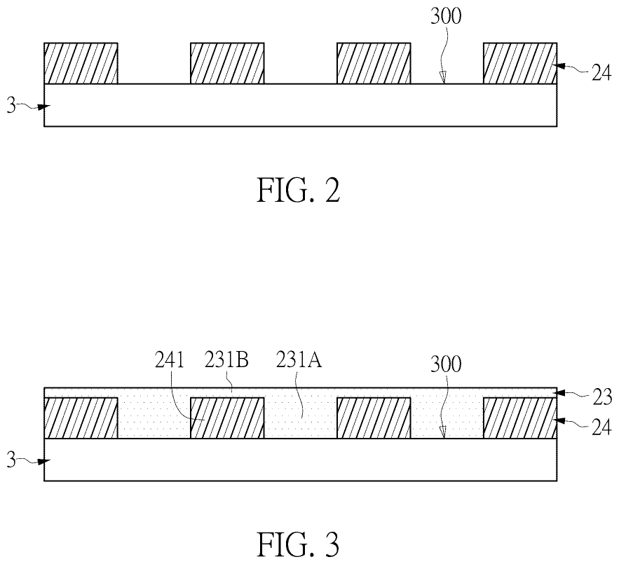

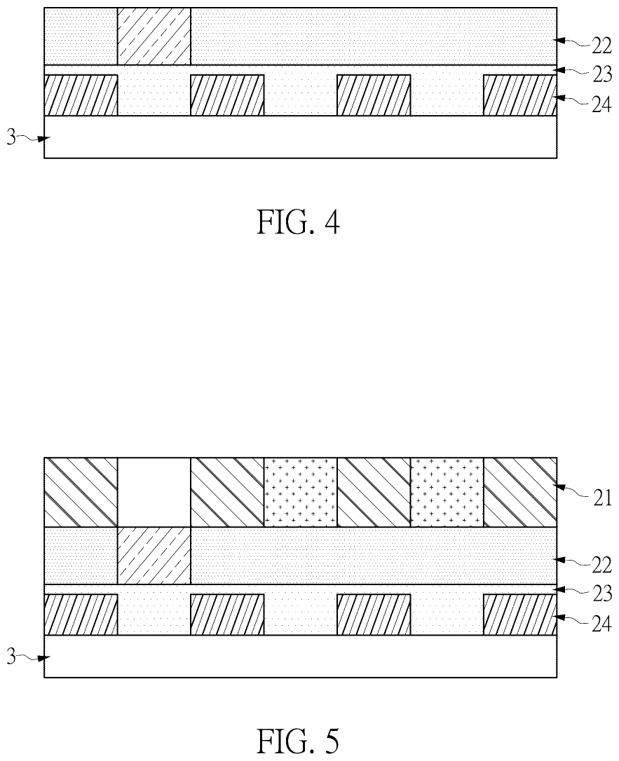

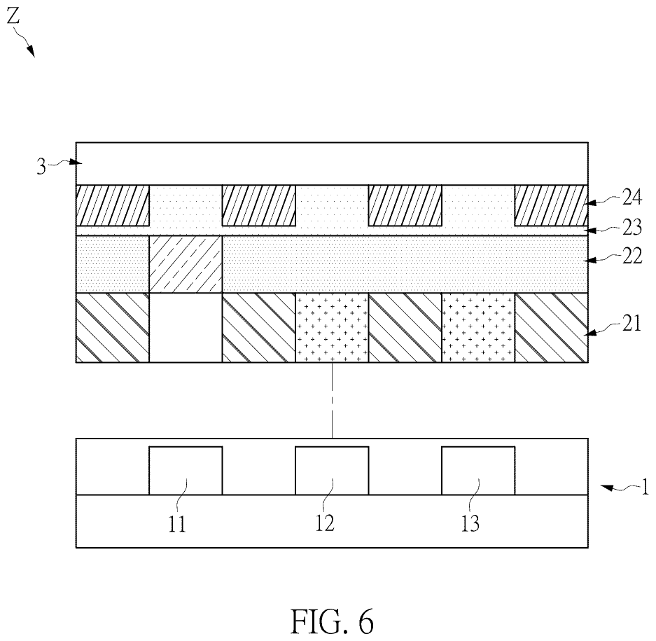

Referring to FIG. 1, which is to be read in conjunction with FIG. 2 to FIG. 6, the display device Z further includes a transparent cover 3. The transparent cover 3 covers the color conversion structure 2 for purposes of protection, and durability of the display device Z can be enhanced. The transparent cover 3 can be a glass cover, but is not limited thereto. In practice, the patterned metal layer 24, the second filter layer 23, the first filter layer 22, and the color conversion layer 21 are sequentially formed on an inner surface 300 of the transparent cover 3. After the color conversion structure 2 is manufactured, the color conversion structure 2 and the transparent cover 3 are both integrated on the blue light substrate 1.

Specifically, in the presence of the patterned metal layer 24, a resin composition containing the yellow pigment is coated onto the patterned metal layer 24, so that a portion of the resin composition is filled into the spaces between the metal spacers 241, and its remaining portion covers the metal spacers 241. Then, the resin composition is baked to form the second filter layer 23. That is to say, without a patterning process (e.g., exposure and development), the second filter layer 23 can be provided with the thick layer regions 231A and the thin layer regions 231B. The thick layer regions 231A are respectively disposed in the spaces between the metal spacers 241, the thin layer regions 231B correspond in position to the metal spacers 241, and each of the metal spacers 241 is interlaid between the transparent cover 3 and a corresponding one of the thin layer regions 231B.

### Beneficial Effects of the Embodiment

In conclusion, in the display device having a high color purity and the color conversion structure thereof provided by the present disclosure, the color conversion structure includes the color conversion layer, the first filter layer disposed on the color conversion layer, and the second filter layer disposed on the first filter layer. The first filter layer includes the another blue light-transmitting region that corresponds in position to the blue light-transmitting region of the color conversion layer. Furthermore, the optical density for each 1 micrometer thickness of the first filter layer within the wavelength range of from 380 nm to 500 nm is from 0.4 to 0.8, and the optical density for each 1 micrometer thickness of the second filter layer within the wavelength range of from 380 nm to 500 nm is from 0.8 to 1.2. In this way, the color purities of the red light and the green light are enhanced, and the brightness of the blue light is ensured, thereby achieving stable, high-quality, and wide color gamut display effects.

Specifically, in the presence of the second filter layer, the excessive portion of the blue light emitted by the first blue light-emitting element and the unwanted portion of the blue light that is emitted by each of the second and third blue light-emitting elements and that is not filtered out by the first filter layer can all be eliminated by the second filter layer. In this way, the color purities of the red light and the green light are enhanced, and the brightness of the blue light is ensured, thereby achieving stable, high-quality, and wide color gamut display effects.

Specifically, the color conversion structure further includes the patterned metal layer, so as to prevent the light from flowing along the second filter layer and negatively affecting the color purity of each color pixel. The patterned metal layer can not only define the predetermined setting region for each color pixel, but can also aid in positioning during the stacking process of the color conversion layer, the first filter layer, and the second filter layer. Moreover, in the presence of the patterned metal layer, exposure and development are not required in the process of forming the second filter layer.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A display device having a high color purity, comprising:
a blue light substrate, wherein the blue light substrate includes a first blue light-emitting element, a second blue light-emitting element, and a third blue light-emitting element that are spaced apart from each other; and
a color conversion structure including:
a color conversion layer disposed on the blue light substrate, wherein the color conversion layer includes a blue light-transmitting region that corresponds in position to the first blue light-emitting element, a green conversion region that corresponds in position to the second blue light-emitting element, and a red conversion region that corresponds in position to the third blue light-emitting element;
a first filter layer disposed on the color conversion layer, wherein the first filter layer includes another blue light-transmitting region that corresponds in position to the blue light-transmitting region, and an optical density for each 1 micrometer thickness of the first filter layer within a wavelength range of from 380 nm to 500 nm is from 0.4 to 0.8; and
a second filter layer disposed on the first filter layer, wherein an optical density for each 1 micrometer thickness of the second filter layer within the wavelength range of from 380 nm to 500 nm is from 0.8 to 1.2.

2. The display device according to claim 1, wherein the color conversion structure includes a patterned metal layer, and the patterned metal layer is disposed on the second filter layer for division of a plurality of sub-pixel units; wherein the first filter layer includes a first blue light-blocking region disposed on at least one side of the another blue light-transmitting region, and the second filter layer includes a second blue light-blocking region; and wherein a blue sub-pixel unit of the plurality of sub-pixel units includes the first blue light-emitting element and the blue light-transmitting region, the another blue light-transmitting region, and the second blue light-blocking region that are sequentially arranged in a direction away from a light-emitting surface of the first blue light-emitting element, a green sub-pixel unit of the plurality of sub-pixel units includes the second blue light-emitting element and the green conversion region, the first blue light-blocking region, and the second blue light-blocking region that are sequentially arranged in a direction away from a light-emitting surface of the second blue light-emitting element, and a red sub-pixel unit of the plurality of sub-pixel units includes the third blue light-emitting element and the red conversion region, the first blue light-blocking region, and the second blue light-blocking region that are sequentially arranged in a direction away from a light-emitting surface of the third blue light-emitting element.

3. The display device according to claim 2, wherein the second blue light-blocking region includes a plurality of thick layer regions and a plurality of thin layer regions that are alternately arranged, and a thickness ratio of the plurality of thick layer regions to the plurality of thin layer regions is from 6:1 to 10:1; and wherein the patterned metal layer includes a plurality of metal spacers that respectively correspond in position to the plurality of thin layer regions, and the plurality of thick layer regions are respectively disposed in a plurality of spaces between the plurality of metal spacers.

4. The display device according to claim 3, further comprising a transparent cover, wherein the transparent cover covers the color conversion structure, the patterned metal layer is disposed between the second filter layer and the transparent cover, and each of the plurality of metal spacers is interlaid between the transparent cover and a corresponding one of the plurality of thin layer regions.

5. The display device according to claim 3, wherein the first filter layer and the second filter layer each contain a yellow pigment, and the yellow pigment is a yellow organic pigment, a yellow inorganic pigment, or a combination thereof.

6. The display device according to claim 5, wherein the first filter layer and the second filter layer are each formed by a photosensitive resin composition that contains the yellow pigment, a thickness of the first filter layer is within a range of from 1.6 μm to 2.5 μm, and a thickness of the plurality of thick layer regions in the second filter layer is within a range of from 0.6 μm to 1 μm; wherein, based on a total weight of the photosensitive resin composition forming the first filter layer being 100 wt %, a content of the yellow pigment in the photosensitive resin composition forming the first filter layer is from 40 wt % to 60 wt %; and wherein, based on a total weight of the photosensitive resin composition forming the second filter layer being 100 wt %, a content of the yellow pigment in the photosensitive resin composition forming the second filter layer is from 10 wt % to 30 wt %.

7. A color conversion structure for converting light emitted from a blue light substrate, the blue light substrate including a first blue light-emitting element, a second blue light-emitting element, and a third blue light-emitting element that are spaced apart from each other, and the color conversion structure comprising:
a color conversion layer disposed on the blue light substrate, wherein the color conversion layer includes a blue light-transmitting region that corresponds in position to the first blue light-emitting element, a green conversion region that corresponds in position to the second blue light-emitting element, and a red conversion region that corresponds in position to the third blue light-emitting element;
a first filter layer disposed on the color conversion layer, wherein the first filter layer includes another blue light-transmitting region that corresponds in position to the blue light-transmitting region, and an optical density for each 1 micrometer thickness of the first filter layer within a wavelength range of from 380 nm to 500 nm is from 0.4 to 0.8; and
a second filter layer disposed on the first filter layer, wherein an optical density for each 1 micrometer thickness of the second filter layer within the wavelength range of from 380 nm to 500 nm is from 0.8 to 1.2.

8. The color conversion structure according to claim 7, wherein the color conversion structure includes a patterned metal layer, and the patterned metal layer is disposed on the second filter layer for division of a plurality of sub-pixel units; wherein the first filter layer includes a first blue light-blocking region disposed on at least one side of the another blue light-transmitting region, and the second filter layer includes a second blue light-blocking region; and wherein a blue sub-pixel unit of the plurality of sub-pixel units includes the first blue light-emitting element and the blue light-transmitting region, the another blue light-transmitting region, and the second blue light-blocking region that are sequentially arranged in a direction away from a light-emitting surface of the first blue light-emitting element, a green sub-pixel unit of the plurality of sub-pixel units includes the second blue light-emitting element and the green conversion region, the first blue light-blocking region, and the second blue light-blocking region that are sequentially arranged in a direction away from a light-emitting surface of the second blue light-emitting element, and a red sub-pixel unit of the plurality of sub-pixel units includes the third blue light-emitting element and the red conversion region, the first blue light-blocking region, and the second blue light-blocking region that are sequentially arranged in a direction away from a light-emitting surface of the third blue light-emitting element.

9. The color conversion structure according to claim 8, wherein the second blue light-blocking region includes a plurality of thick layer regions and a plurality of thin layer regions that are alternately arranged, and a thickness ratio of the plurality of thick layer regions to the plurality of thin layer regions is from 6:1 to 10:1; and wherein the patterned metal layer includes a plurality of metal spacers that respectively correspond in position to the plurality of thin layer regions, and the plurality of thick layer regions are respectively disposed in a plurality of spaces between the plurality of metal spacers.

10. The color conversion structure according to claim 9, wherein the first filter layer and the second filter layer each contain a yellow pigment, and the yellow pigment is a yellow organic pigment, a yellow inorganic pigment, or a combination thereof.

11. The color conversion structure according to claim 10, wherein the first filter layer and the second filter layer are each formed by a photosensitive resin composition that contains the yellow pigment, a thickness of the first filter layer is within a range of from 1.6 μm to 2.5 μm, and a thickness of the plurality of thick layer regions in the second filter layer is within a range of from 0.6 μm to 1 μm; wherein, based on a total weight of the photosensitive resin composition forming the first filter layer being 100 wt %, a content of the yellow pigment in the photosensitive resin composition forming the first filter layer is from 40 wt % to 60 wt %; and wherein, based on a total weight of the photosensitive resin composition forming the second filter layer being 100 wt %, a content of the yellow pigment in the photosensitive resin composition forming the second filter layer is from 10 wt % to 30 wt %.
